(19) United States
(12) Patent Application Publication
(10) Pub. No.: US 2025/0245770 A1
(43) Pub. Date: Jul. 31, 2025

(54) OPTIMAL REGIONAL ARCHITECTURE GENERATION FOR EFFICIENT NATIONAL TRANSPORT

(71) Applicant: UT-Battelle, LLC, Oak Ridge, TN (US)

(72) Inventors: Vivek Anand Sujan, Knoxville, TN (US); Adam G. Siekmann, Oak Ridge, TN (US); Ruixiao Sun, Knoxville, TN (US)

(21) Appl. No.: 19/038,835

(22) Filed: Jan. 28, 2025

Related U.S. Application Data
(60) Provisional application No. 63/626,084, filed on Jan. 29, 2024.

(51) Int. Cl. G06Q 50/40; G06F 30/18

(52) U.S. Cl. CPC G06Q 50/40; G06F 30/18

(57) ABSTRACT

A method for generating an optimized regional architecture for efficient national transport is provided. The method integrates vehicle powertrain architectures, operations logistics, and energy pathways to optimize both behind-the-fence and public access energy dispensing solutions supported by local distributed energy resource equipment and centralized fuel sourcing. More specifically, the method provides an optimal regional architecture for electrified national transport modeling. The method assimilates critical data for seasonal operating scenarios to provide a regional specific constrained-optimal infrastructure deployment solution. As discussed herein, the present invention provides local government agencies, industry end users, energy suppliers, and equipment providers with a flexible planning tool to navigate the deployment of electrified freight transportation systems in view of localized constraints.

### CROSS-REFERENCE TO RELATED APPLICATIONS

This application claims the benefit of U.S. Provisional Application 63/626,084, filed Jan. 29, 2024, the disclosure of which is incorporated by reference in its entirety.

### STATEMENT REGARDING FEDERALLY SPONSORED RESEARCH AND DEVELOPMENT

This invention was made with government support under Contract No. DE-AC05-00OR22725 awarded by the U.S. Department of Energy. The government has certain rights in the invention.

### BACKGROUND OF THE INVENTION

The energy storage characteristics of emerging electrified commercial vehicles present a significant departure from today's mature liquid fuel infrastructure. Accordingly, there exists a new opportunity and need for co-optimizing the development of electrified commercial vehicles, their usage, their recharging infrastructure, and the supporting electrical grid. Unlike their diesel counterparts, which were optimized over the past 120 years, there is a wide disparity of solutions emerging from electrified powertrains. This requires the end user to define specifications for the power plant, on-board energy storage, and the charging infrastructure. While small and intermittent loads are readily accommodated in this manner, the paradigm of electrified heavy-duty transport will necessitate greater planning and coordination to mitigate the adverse effects of reactive solutions, e.g., higher net carbon emissions and regional loss of power.

At present, this disconnected effort necessitates that end users of electrified commercial vehicles rely on behind-the-fence energy management operations, e.g., private charging infrastructures, which drives up asset cost, potential downtime, and net carbon emissions. Similarly, as charging asset deployment plans progress, organizations are faced with the challenging task of determining the most effective phase-in, e.g., locations, quantities, and power ratings, of this super-system. Only by introducing a unified systems architecture that brings together considerations can widespread adoption of electrified powertrains be achieved.

### SUMMARY OF THE INVENTION

A method for generating an optimized regional architecture for efficient national transport is provided. The method integrates vehicle powertrain architectures, operations logistics, and energy pathways to optimize both behind-the-fence and public access energy-dispensing solutions supported by local distributed energy resource equipment and centralized fuel sourcing. More specifically, the method provides an optimal regional architecture for electrified national transport modeling. The method assimilates critical data for seasonal operating scenarios to provide a regional specific constrained-optimal infrastructure deployment solution. As discussed herein, the present invention provides local government agencies, industry end users, energy suppliers, and equipment providers with a flexible planning tool to navigate the deployment of electrified or decarbonized freight transportation systems in view of localized constraints.

In one embodiment, the method includes developing a regional strategy for electrified or decarbonized vehicles and related charging infrastructure by using critical information such as stakeholder inputs and stake-holder independent data. As a first step, an operating design domain is created, the operating design domain being specific to a geographic region. The method then proceeds through three interconnected modeling steps: (a) freight transport modeling; (b) vehicle energy modeling; and (c) energy infrastructure modeling. Freight transport modeling uses freight-specific data and aspects of the operating design domain to simulate freight transport within the geographic region of interest. Vehicle energy modeling uses vehicle energy-related data, aspects of the overall design domain, and results from the freight transport model to analyze vehicle energy needs. Lastly, energy infrastructure modeling leverages energy infrastructure-specific data, aspects of the operating design domain, and results from the vehicle energy model to develop infrastructure requirements. These models are iteratively refined through a process of co-optimization until a defined performance target is achieved. Each iteration updates the models based on the results of the previous iteration, improving the accuracy and efficiency of the proposed solution. Once the defined performance target is met, the method produces actionable outputs tailored to the region, detailing the required technology, infrastructure architecture, and operational qualifications necessary for implementing the charging strategy.

In a species of the foregoing embodiment, a non-transitory computer-readable memory encodes instructions that, when executed by a data processor, cause the data processor to perform operations for supporting the transition to decarbonized vehicle fleets. These operations include receiving stakeholder inputs relating to logistical requirements, carbon emission constraints, and a desired timeframe for the transition to decarbonized vehicles. Based on these inputs, the data processor models two or more vehicle fleet configurations, generates comparative scenarios for at least two such vehicle fleet configurations, and outputs an optimized transition pathway. The transition pathway identifies spatio-temporal refueling or recharging solutions tailored to a stakeholder-defined region of interest. The modeled fleet configurations may include a combination of battery electric vehicles, fuel cell electric vehicles, hybrid vehicles, and renewable fuel-based internal combustion engine vehicles. The identified refueling or recharging solutions incorporate a mix of mobile and stationary charging/fueling platforms, ensuring flexible and region-specific energy solutions. The optimized transition pathway also includes an analysis of the cost-to-operate or cost-to-own the selected vehicle fleet configuration(s), providing stakeholders with actionable insights into the economic implications of a selected decarbonization pathway.

The present invention has broad utility for assisting stakeholders in the transition of all or a portion of existing vehicle fleets and/or charging/fueling infrastructures. For example, the present invention can aid in the realization of decarbonized road freight transport by providing stakeholders with regional solutions that meet decarbonization goals within cost constraints. The present invention integrates competing heavy-duty commercial vehicle and infrastructure architectural needs. It creates a co-optimized deployment roadmap that can inform and direct key decision personnel in the entire value chain of this ecosystem. The present invention accelerates the implementation of clean energy transportation solutions by providing tools for evaluating the energy impacts of new mobility solutions to increase energy productivity for individuals and businesses alike. The present invention has broad applicability to the transportation, energy, and utility sectors. While primarily directed to commercial freight, the present invention is applicable to any battery-dominant powertrain, including battery electric vehicles, fuel cell electric vehicles, and hybrid electric vehicles, as well as renewable fuel powertrains, including renewable diesel and renewable natural gas, for both on-highway and off-highway applications.

These and other features and advantages of the present invention will become apparent from the following description of the invention, when viewed in accordance with the accompanying drawings and appended claims.

### BRIEF DESCRIPTION OF THE DRAWINGS

FIG. 1 illustrates the inputs, integrated co-optimization, and outputs of a modeling framework in accordance with the present invention.

FIG. 2 is a flow-chart illustrating a method for generating a regional architecture for a charging/refueling infrastructure in accordance with one embodiment.

FIG. 3 illustrates a computer model for evaluating decarbonized vehicle and infrastructure solutions for commercial freight and other applications.

### DETAILED DESCRIPTION OF THE CURRENT EMBODIMENT

The current embodiment is directed to a method for generating a regional architecture for a charging/refueling infrastructure for electrified or decarbonized transportation. The method is embodied in non-transitory computer-readable memory containing instructions that, when executed by one or more processors, cause the one or more processors to perform a series of method steps. The resulting architecture is dynamically adjustable, allowing for regional characterizations arising from different stakeholder motivations in this ecosystem. With an overarching goal of assisting stakeholders reach their carbon neutral goals, the present method is configured to produce outputs that can be used to develop realistic and scalable charging solutions.

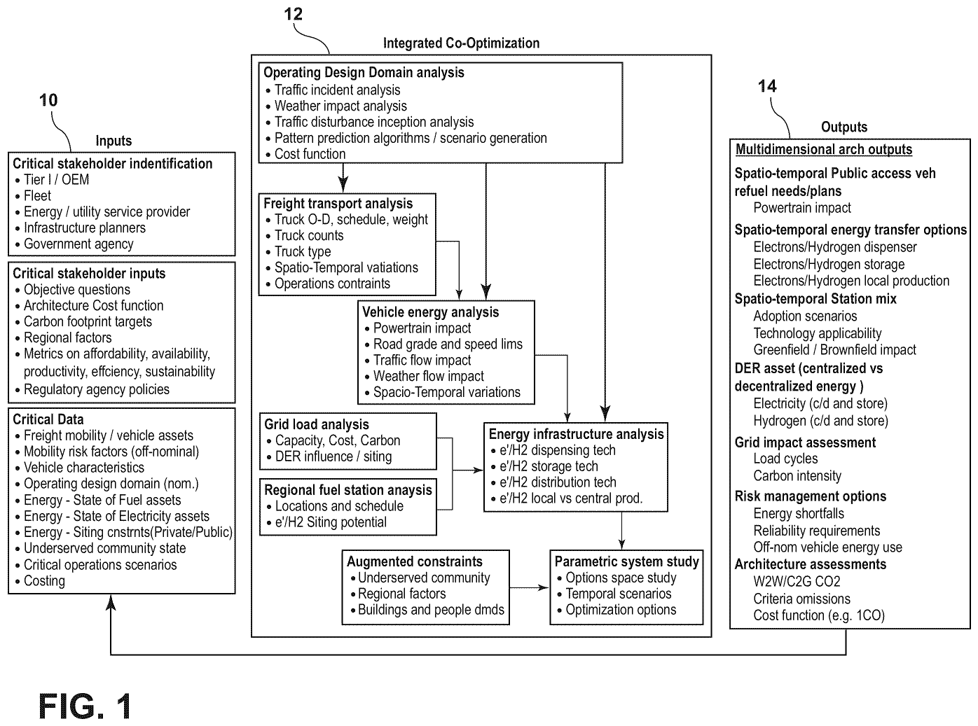

Before the method is discussed in detail, a generalized discussion of the modeling framework is discussed in connection with FIG. 1. The modeling framework includes a series of inputs 10, co-optimization 12, and outputs 14. The inputs 10 can originate from identified stakeholders, which can include strategic enabling partners in the form of fleet and energy/utility providers in the various regions of interest, suppliers and original equipment manufacturers, and local planning agencies. Stakeholders provide objectives and decarbonization targets, analysis metrics, and performance costs functions. This analysis can hinge on key and accurate data sets that may be obtained directly or indirectly from stakeholders, federal agencies, research laboratories, and other aligned industry sources. In the absence of these data sets, parametric sensitivity studies may be performed to help bound the results of the analysis. To achieve the desired outputs 14, the modeling framework includes four modeling substages. The substages factor real-world scenarios including traffic, weather, and road conditions based on the time of day and seasonal factors. First, the freight flow system is modeled. This includes origin-to-destination, routes, schedule, weights, vehicle count, network behavior, and other fleet attributes. Second, the vehicle systems are modeled using one-dimensional longitudinal dynamics to determine energy efficiency and consumption needs, including emission changes. Third, the energy (e.g., electrical grid and hydrogen) pathways to the vehicle are modeled to identify the capacity, carbon intensity, and cost of these options. This will be dependent on models of the grid load and regional fuel stations. The latter also includes siting potential for hydrogen and hydrogen supporting systems and/or electricity and electricity supporting systems. Siting can also include other fuels as an independent energy source or for generating electricity, including renewable diesel, renewable natural gas, ammonia, biofuels, and green aviation fuels. In addition to siting, the available energy pathways can include fuel generation and transport (pipeline, rail, and/or road). The fourth and final step includes co-optimization using the results from the previous three modeling steps. This step further includes detailed situational constraints arising from the baseline public and private refueling arrangements, as well as local underserved community considerations. The resulting outputs 14 include spatio-temporal energy transfer options, spatio-temporal station scenarios, grid impact assessments, risk management options, architectural outputs, and total cost of ownership, to name but a few.

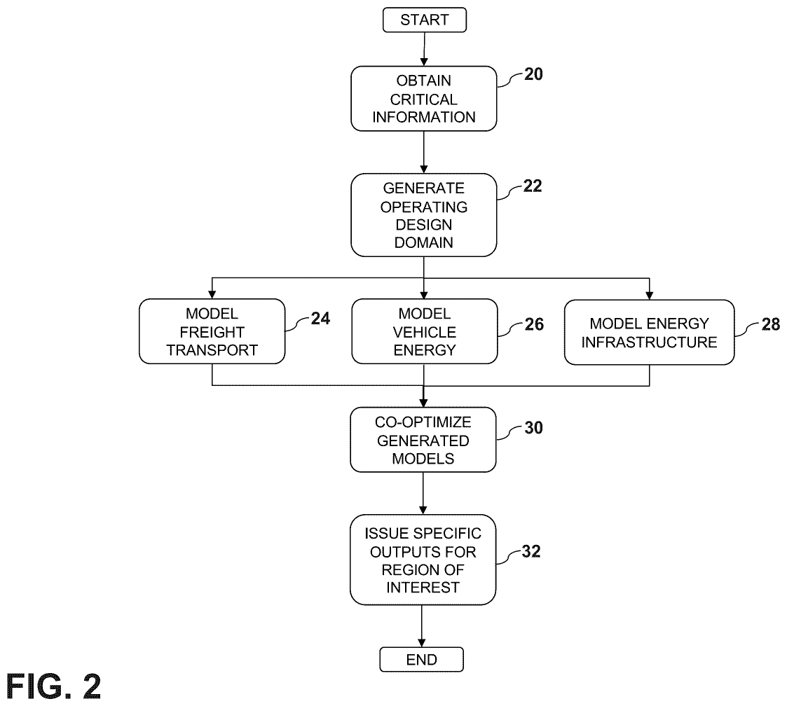

Referring now to FIG. 2, a flow charting for implementing the method of the present invention is illustrated. At step 20, the method generally includes obtaining critical information comprising stakeholder identification, stakeholder inputs, and stakeholder-independent data. This step involves the identification of key parties (stakeholders), collecting their requirements (stakeholder inputs), and incorporating additional relevant data from independent sources that do not rely on stakeholder contributions (stakeholder-independent data). The stakeholders can include, for example, original equipment manufacturers, tier-1 suppliers, commercial vehicle fleets, energy service providers, infrastructure planners, or government agencies. The stakeholder inputs can include carbon footprint targets, regional factors, regulatory agency policies, or metrics on availability, productivity, efficiency, or sustainability. Lastly, the stakeholder-independent data can include freight vehicle assets, mobility risk factors, vehicle characteristics, nominal operating design domains, state of fuel assets, state of electricity assets, siting constraints, or critical operation scenarios, by non-limiting example.

At step 22, the method includes generating an operating design domain associated with a geographic region of interest based on a region-specific subset of the critical information obtained at step 20. Generating an operating design domain involves creating a framework or a set of rules that defines how a system will operate within a specific geographic area. Creating this framework involves using region-specific information to analyze factors such as traffic incidents, the impact of weather on transportation systems, and the causes of traffic disturbances. Additionally, creating this framework includes predicting patterns such as vehicle flow, energy demand, or infrastructure usage to ensure the system is optimized for real-world conditions in that area. The operating design domain is therefore customized for the specific region of interest and can be updated as new data, technologies, or regulations emerge.

At step 24, the method includes modeling freight transport based on a subset of the critical information, as well as aspects of the operating design domain that pertain to freight movement. Modeling freight transport takes into account various factors, including the origin and destination of commercial fleet vehicles, their schedules, and their weights. Modeling freight transport also considers vehicle counts, the vehicle types, and spatio-temporal variations such as changes in traffic patterns over time and across locations. Additionally, modeling freight transport incorporates operating constraints to create an accurate representation of freight transport within the defined parameters.

At step 26, the method includes modeling vehicle energy based on a subset of the critical information. This step utilizes a subset of the critical information that is specific to energy consumption, aspects of the operating design domain relevant to vehicle energy, and the results of freight modeling (step 24). This process considers factors such as the impact of the vehicle's powertrain on energy use, the influence of road grade and speed limits, and the effects of traffic flow on energy efficiency. Additionally, it accounts for weather-related impacts, such as temperature and precipitation, and spatio-temporal variations, including changes in conditions over time and across different locations. These elements are combined to create a detailed and dynamic model of vehicle energy requirements within the defined operational parameters.

At step 28, the method includes modeling energy infrastructure. This step includes creating a comprehensive framework for designing and optimizing the energy systems required to support a specific region. This step uses a subset of critical information focused on energy infrastructure, aspects of the operating design domain relevant to energy systems, and the results of vehicle energy modeling. An important step includes analyzing grid load to understand the current and future capacity of the regional power grid, ensuring that it can handle the additional demand from electric vehicles and other energy-intensive systems. The model also evaluates existing regional fuel stores, determining their potential to serve as energy hubs for electric vehicle refueling or recharging. Additionally, this step considers advance energy technologies, including energy-dispersing systems (such as dynamic wireless charging platforms), energy storage solutions (such as battery banks or hydrogen fuel cells), and energy distribution technologies (such as charging station networks or power transmission lines). By integrating these factors, the energy infrastructure model provides a detailed understanding of the energy infrastructure needs for electric vehicle refueling or recharging in the geographic sub-region of interest.

At step 30, the method includes co-optimizing each of the freight transport, vehicle energy, and energy infrastructure models discussed above. This step is implemented as an iterative process that integrates and refines these interconnected models to achieve a defined performance target. In one embodiment, this step begins by using the initial data sets that are specific to freight transport, vehicle energy, and energy infrastructure from their respective modeling. The results from each model are analyzed and used to update the corresponding subsets of critical information, such as transport schedules, vehicle energy consumption patterns, and grid load capacity.

In subsequent iterations, updated data from each model is fed into the others, creating a feedback loop that continuously enhances the accuracy and alignment of the freight transport, vehicle energy, and energy infrastructure models. For example, insights from the freight transport model, such as shifts in vehicle demand, inform adjustments to energy consumption models, which in turn shape the requirements and design of the energy infrastructure model. Each iteration evaluates the system's overall performance against predefined metrics, such as efficiency, sustainability, or system reliability. This iterative co-optimization ensures all components—freight transport, vehicle energy, and energy infrastructure—are dynamically adjusted to work harmoniously. By refining these models iteratively, the method converges on a solution that meets or exceeds the performance target, tailored for the specific regional and/or operational context.

At step 32, once the performance target has been met through iterative modeling and optimization, the method culminates in the issuance of a comprehensive set of outputs. These outputs are derived from the combined results of the freight transport modeling, vehicle energy modeling, and energy infrastructure modeling and include vehicle architecture, local energy-dispensing architecture, and region-specific energy backbone infrastructure. They offer actionable insights and solutions that are tailored to the region's unique requirements. More specifically, the outputs provide the stakeholders with recommendations for implementing advanced technologies, such as energy-dispersing systems or dynamic wireless charging platforms, in an effort to meet cost constraints and carbon constraints. The outputs also provide detailed infrastructure architectures, outlining the design and placement (siting) of charging stations, grid enhancements, fuel generation (e.g., hydrogen generation by electrolysis), fuel transport (e.g., pipeline, rail, and/or road), and energy storage systems to meet current and projected demands. Additionally, the outputs define usage qualifications, such as operating conditions, safety protocols, and regulatory compliance, ensuring that the proposed solutions are practical, scalable, and aligned with local policies and environmental goals. This tailored approach not only facilitates the deployment of a robust and efficient energy and transport ecosystem, but also provides stakeholders with a clear roadmap for integrating cutting-edge solutions into the region's transportation architecture.

To reiterate, the present invention integrates competing heavy-duty commercial freight and infrastructure architectural needs. It creates a co-optimized deployment roadmap that can inform and direct key decision personnel in the entire value chain of this ecosystem. The present invention accelerates the implementation of clean energy transportation solutions by providing tools for evaluating the energy impacts of new mobility solutions to increase energy productivity for individuals and businesses alike. The present invention has broad applicability to the transportation, energy, and utility sectors. While primarily directed to commercial freight, including line haul, regional haul, drayage, and last-mile delivery, the present invention is applicable to any battery-dominant platform, including battery electric vehicles, fuel cell electric vehicles, and hybrid electric vehicles, including on-highway and off-highway applications.

In a further example, the present invention provides a comprehensive model that aids stakeholders in assessing the technical, environmental, regulatory, and/or economic feasibility of region-specific decarbonized solutions for freight transport. The comprehensive model evaluates the adoption of alternative fuel technologies, such as battery electric vehicles, hydrogen fuel cell vehicles, as well as advanced biofuels such as renewable diesel and renewable natural gas, while simultaneously considering the associated infrastructure requirements for charging/refueling for evaluating the total cost of ownership. The comprehensive model also incorporates interactions between road freight energy demands and power grid capacity, with an emphasis on the integration of renewable energy sources such as solar and wind.

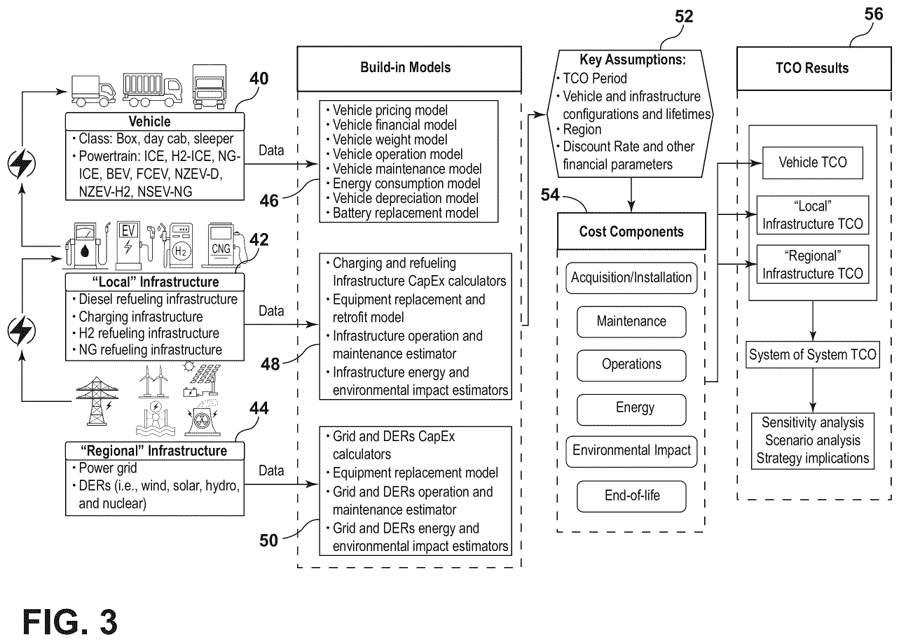

Referring now to FIG. 3, one implementation of this model is illustrated. At the input stage, users provide vehicle data 40, local infrastructure data 42, and regional infrastructure data 44 to build three discrete but interconnected modules: a vehicle module 46, a local infrastructure module 48, and a regional infrastructure module 50. The vehicle module 46 is segmented into three vehicle classes, each with unique energy requirements: box trucks, day cabs, and sleeper cabs. The vehicle module 46 encompasses several powertrains to provide a comprehensive view of potential pathways for decarbonization. These include diesel internal combustion engine vehicles, hydrogen internal combustion engine vehicles, natural gas internal combustion vehicles, battery electric vehicles, hydrogen fuel cell electric vehicles, near-zero electric vehicles with hydrogen fuel, near-zero electric vehicles with natural gas, and near-zero electric vehicles with diesel.

The local infrastructure module 48 captures the costs and logistical complexities associated with a variety of recharging and refueling modalities. The local infrastructure module 48 includes the installation, operation, and maintenance of diesel, hydrogen, and natural gas refueling infrastructures, each with distinct capital and operational expense profiles. Additionally, local infrastructure module addresses the intricate requirements of electric vehicle charging stations, from the deployment of fast-charging networks and associated grid connections to the integration of energy storage systems for peak demand management. By examining these infrastructure elements in detail, the module provides actional insights into technical and economic considerations related to a resilient and scalable energy network for decarbonized freight transport.

The regional infrastructure module 50 is focused on evaluating the costs associated with energy provision through the power grid. This evaluation is supplemented by distributed energy resource (DER) assets, including wind, solar, hydro, and nuclear. The DER assets may be used to augment the local electrical grid and can also be used to augment other energy backbones. In addition, as the electricity generated by the DER assets can be converted into some fuels such as hydrogen, methanol, synthetic diesel, or methane by non-limiting example. The regional infrastructure module 50 also accounts for the financial requirements for capital investments needed to upgrade the grid infrastructure. The regional infrastructure module also assesses the integration of renewal energy sources into the existing energy network. By incorporating a forward-looking perspective, this module 50 provides a comprehensive analysis of future energy supply costs, taking into account evolving demands, advancements in technology, and the shift toward sustainable energy solutions.

The modules 46, 48, 50 are then co-optimized in view of certain assumptions 52 to provide stakeholders with a total cost of ownership (TCO) model. The assumptions 52 can be variable, e.g., provided by the end-user, or fixed. The assumptions can include, for example, the TCO period, vehicle and infrastructure configurations and lifetimes, the geographic region of interest, and any financial parameters. The TCO model defines and categories six primary cost components 54 that comprehensively capture the technical, financial, and environmental implications of adopting the decarbonization solution offered by the TCO model.

As more particularly shown in FIG. 3, the cost components 54 can include acquisition or installation costs, maintenance costs, operational costs, energy consumption costs, end-of-life considerations, and environmental impacts. The acquisition and installation costs represent upfront expenses associated with the purchase or leasing of vehicles or infrastructure, including hardware and software. The maintenance costs represent recurring costs for repairs, replacement, and regular servicing to ensure optimal performance over the lifespan of the vehicles and the refueling/recharging infrastructure. The operational costs represent the expenses for operating the vehicles and the refueling/recharging infrastructure, including labor and insurance. The energy consumption costs represent the fuel or energy used during operation, considering variations in energy prices and efficiency across powertrain types. The end-of-life considerations represent cost or savings associated with the decommissioning, disposal, or recycling of vehicles or equipment, factoring in potential resale or salvage value. Lastly, the environmental impacts represent the monetary valuation of the vehicle's carbon footprint, emissions, and other ecological effects, calculated to reflect penalties or incentives.

As also shown in FIG. 3, the TCO model provides its results 56 in the form of vehicle TCO, local infrastructure TCO, and regional infrastructure TCO. The TCO model evaluates these costs across both short-term and long-term horizons. End users can customize the TCO model to account for specific vehicle and infrastructure configurations and regionally adjusted cost variables, ensuring highly tailored and accurate analyses. By integrating and interconnecting it three core modules into a unified analytical layer, the TCO model calculates a “system of systems” TCO. This holistic approach represents the aggregated cost for each vehicle type within its respective infrastructure and operational context. Such integration enables direct comparisons between alternative fuel technologies and traditional diesel options. In addition, a robust scenario analysis allows the end-user to compare different pathways for vehicle adoption and infrastructure development under varying technological, economic, and policy conditions.

The above description is that of current embodiments of the invention. Various alterations and changes can be made without departing from the spirit and broader aspects of the invention as defined in the appended claims, which are to be interpreted in accordance with the principles of patent law including the doctrine of equivalents. Any reference to elements in the singular, for example, using the articles “a,” “an,” “the,” or “said,” is not to be construed as limiting the element to the singular.

1. Non-transitory computer readable memory encoding instructions that, when executed by a data processor, cause the data processor to perform operations comprising:
obtaining critical information comprising stakeholder identification, stakeholder inputs, and stakeholder-independent data;
generating an operating design domain associated with a geographic region of interest based on a region-specific subset of the critical information;
(i) modeling freight transport based on a freight transport-specific subset of the critical information and based on freight transport-specific aspects of the operating design domain;
(ii) modeling vehicle energy based on a vehicle energy-specific subset of the critical information, based on vehicle energy-specific aspects of the operating design domain, and further based on results of the freight transport modeling;
(iii) modeling energy infrastructure based on an energy infrastructure-specific subset of the critical information, based on an energy infrastructure-specific subset of the critical information, based on energy infrastructure-specific aspects of the operating design domain, and further based on results of the vehicle energy modeling;
co-optimizing the modeled freight transport, the modeled vehicle energy, and the modeled energy infrastructure by iteratively performing the sequence of operations (i) to (iii) until a performance target is met, wherein each such iteration uses the freight transport-specific subset, the vehicle energy-specific subset, and the energy infrastructure-specific subset as updated based on the freight transport modeling results, the vehicle energy modeling results, and the energy infrastructure modeling results of the previous iteration; and
issuing, based on the freight transport modeling results, the vehicle energy modeling results, and the energy infrastructure modeling results associated with the met performance target, a set of region of interest-specific outputs that provide actionable technology, infrastructure architecture, and usage qualifications.

2. The computer readable memory of claim 1, wherein:
the stakeholder identification information comprises one or more of original equipment manufacturers, commercial vehicle fleets, energy service providers, infrastructure planners, or government agencies;
the stakeholder inputs comprise one or more of carbon footprint targets, regional factors, regulatory agency policies, or metrics on availability, productivity, efficiency, or sustainability; and
the stakeholder-independent data comprises one or more of freight vehicle assets, mobility risk factors, vehicle characteristics, nominal operating design domains, state of fuel assets, state of electricity assets, siting constraints, or critical operation scenarios.

3. The computer readable memory of claim 1, wherein the set of region of interest-specific outputs comprise one or more of:
spatio-temporal public access vehicle refuel needs;
spatio-temporal energy transfer options;
a spatio-temporal station mix;
a distributed energy resource (DER) asset;
a grid impact assessment;
risk management options; or
architecture assessments.

4. The computer readable memory of claim 1, wherein generating an operating design domain comprises one or more of:
analyzing traffic incidents;
analyzing weather impact;
analyzing traffic disturbance inception; or
predicting patterns.

5. The computer readable memory of claim 1, wherein modeling freight transport comprises accounting for one or more of:
vehicle origin-destination, schedule, and weight;
vehicle counts;
vehicle type;
spatio-temporal variations; or
operating constraints.

6. The computer readable memory of claim 1, wherein modeling vehicle energy comprises accounting for one or more of:
powertrain impact;
road grade and speed limits;
traffic flow impact;
weather flow impact; or
spatio-temporal variations.

7. The computer readable memory of claim 1, wherein modeling the energy infrastructure comprises:
analyzing grid load;
analyzing regional fuel stations; and
accounting for one or more of:
energy dispersing technology,
energy storage technology,
energy distribution technology, or
a comparison of localized versus centralized energy production.

8. The computer readable memory of claim 1, wherein the performance target includes at least one of a cost target and a carbon target.

9. The computer readable memory of claim 1, wherein the set of region of interest-specific outputs includes locations for the placement of mobile charging stations within the region of interest.

10. The computer readable memory of claim 1, wherein the set of region of interest-specific outputs includes locations for the placement of energy storage systems within the region of interest, the energy storage systems including liquid or gaseous fuels.

11. The computer readable memory of claim 1, wherein the set of region of interest-specific outputs includes a combination of two or more vehicle platforms capable of meeting the performance target, the vehicle platforms including at least one of battery electric vehicles, fuel cell electric vehicles, hybrid electric vehicles, and internal combustion vehicles.

12. The computer readable memory of claim 11, wherein the set of region of interest-specific outputs further includes an optimized local energy dispensing architecture and an optimized regional energy infrastructure.

13. The computer readable memory of claim 1, wherein the set of region of interest-specific outputs comprise a plurality of distributed energy resources (DERs), the DERs being configured to augment an existing electrical infrastructure or an existing liquid fuel infrastructure.

14. A method comprising:
obtaining critical information comprising stakeholder identification, stakeholder inputs, and stakeholder-independent data;
generating an operating design domain associated with a geographic region of interest based on a region-specific subset of the critical information;
(i) modeling freight transport based on a freight transport-specific subset of the critical information and based on freight transport-specific aspects of the operating design domain;
(ii) modeling vehicle energy based on a vehicle energy-specific subset of the critical information, based on vehicle energy-specific aspects of the operating design domain, and further based on results of the freight transport modeling;
(iii) modeling energy infrastructure based on an energy infrastructure-specific subset of the critical information, based on an energy infrastructure-specific subset of the critical information, based on energy infrastructure-specific aspects of the operating design domain, and further based on results of the vehicle energy modeling;
co-optimizing the modeled freight transport, the modeled vehicle energy, and the modeled energy infrastructure by iteratively performing the sequence of operations (i) to (iii) until a performance target is met, wherein each such iteration uses the freight transport-specific subset, the vehicle energy-specific subset, and the energy infrastructure-specific subset as updated based on the freight transport modeling results, the vehicle energy modeling results, and the energy infrastructure modeling results of the previous iteration; and
issuing, based on the freight transport modeling results, the vehicle energy modeling results, and the energy infrastructure modeling results associated with the met performance target, a set of region of interest-specific outputs that provide actionable technology, infrastructure architecture, and usage qualifications.

15. The method of claim 14:
the stakeholder identification information comprises one or more of original equipment manufacturers, commercial vehicle fleets, energy service providers, infrastructure planners, or government agencies;
the stakeholder inputs comprise one or more of carbon footprint targets, regional factors, regulatory agency policies, or metrics on availability, productivity, efficiency, or sustainability; and
the stakeholder-independent data comprises one or more of freight vehicle assets, mobility risk factors, vehicle characteristics, nominal operating design domains, state of fuel assets, state of electricity assets, siting constraints, or critical operation scenarios.

16. The method of claim 14, wherein the set of region of interest-specific outputs comprise one or more of:
spatio-temporal public access vehicle refuel needs;
spatio-temporal energy transfer options;
a spatio-temporal station mix;
a distributed energy resource (DER) asset;
a grid impact assessment;
risk management options; or
architecture assessments.

17. The method of claim 14, wherein generating an operating design domain comprises one or more of:
analyzing traffic incidents;
analyzing weather impact;
analyzing traffic disturbance inception; or
predicting patterns.

18. The method of claim 14, wherein modeling freight transport comprises accounting for one or more of:
vehicle origin-destination, schedule, and weight;
vehicle counts;
vehicle type;
spatio-temporal variations; or
operating constraints.

19. The method of claim 14, wherein modeling vehicle energy comprises accounting for one or more of:
powertrain impact;
road grade and speed limits;
traffic flow impact;
weather flow impact; or
spatio-temporal variations.

20. The method of claim 14, wherein modeling the energy infrastructure comprises:
analyzing grid load;
analyzing regional fuel stations; and
accounting for one or more of:
energy dispersing technology,
energy storage technology,
energy distribution technology, or
a comparison of localized versus centralized energy production.

21. The method of claim 14, wherein the performance target includes at least one of a cost target and a carbon target.

22. The method of claim 14, wherein the set of region of interest-specific outputs includes locations for the placement of mobile charging stations within the region of interest.

23. The method of claim 14, wherein the set of region of interest-specific outputs includes locations for the placement of energy storage systems within the region of interest, the energy storage systems including liquid or gaseous fuels.

24. The method of claim 14, wherein the set of region of interest-specific outputs comprise a plurality of distributed energy resources (DERs), the DERs being configured to augment an existing electrical infrastructure or an existing liquid fuel infrastructure.

25. Non-transitory computer readable memory encoding instructions that, when executed by a data processor, cause the data processor to perform operations comprising:
receiving stakeholder inputs relating to stakeholder-specific logistical requirements, carbon emission constraints, and a desired decarbonized transitionary timeframe; and
modelling two or more vehicle fleet configurations based on the stakeholder inputs;
generating comparative scenarios of at least two of the vehicle fleet configurations; and
outputting an optimized transition pathway for achieving a selected one of the at least two vehicle fleet configurations, the optimized transition pathway including an identification of spatio-temporal refueling or recharging solutions within a stakeholder-selected region-of-interest.

26. The memory of claim 25, further including co-optimizing the at least two vehicle fleet configurations to meet a desired performance target.

27. The memory of claim 25, wherein the two or more vehicle fleet configurations include a combination of two or more of: battery electric vehicles; fuel cell electric vehicles; hybrid vehicles, and renewable fuel-based internal combustion engine vehicles.

28. The memory of claim 25, wherein the spatio-temporal refueling or recharging solutions includes a combination of mobile charging platforms and stationary charging platforms.

29. The memory of claim 25, wherein the optimized transition pathway includes a cost-to-operate or a cost-to-own a selected to one of the at least two vehicle fleet configurations.
